(19) United States
(12) Patent Application Publication
(10) Pub. No.: US 2021/0140043 A1
(43) Pub. Date: May 13, 2021

(54) DEPOSITION OF PURE METAL FILMS

(71) Applicant: Lam Research Corporation, Fremont, CA (US)

(72) Inventors: Shruti Vivek Thombare, Sunnyvale, CA (US); Gorun Butail, Fremont, CA (US); Patrick A. van Cleemput, San Jose, CA (US); Ilanit Fisher, San Jose, CA (US)

(21) Appl. No.: 17/250,452

(22) PCT Filed: Jul. 25, 2019
(86) PCT No.: PCT/US2019/043514

§ 371 Date: Jan. 22, 2021

Related U.S. Application Data
(60) Provisional application No. 62/703,788, filed on Jul. 26, 2018.

(51) Int. Cl. C23C 16/455; C23C 16/06

(52) U.S. Cl. CPC C23C 16/45527; C23C 16/06

(57) ABSTRACT

Provided herein are methods and apparatus for deposition of pure metal films. The methods involve the use of oxygen-containing precursors. The metals include molybdenum (Mo) and tungsten (W). To deposit pure films with no more than one atomic percentage oxygen, the reducing agent to metal precursor ratio is significantly greater than 1. Molar ratios of 100:1 to 10000:1 may be used in some embodiments.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Deposition of metals is an integral part of many semiconductor fabrication processes. These materials may be used for horizontal interconnects, vias between adjacent metal layers, and contacts between metal layers and devices. However, as devices shrink and more complex patterning schemes are utilized in the industry, uniform deposition of low resistivity metal films becomes a challenge. Deposition in complex high aspect ratio structures such as 3D NAND structures is particularly challenging.

### SUMMARY

One aspect of the disclosure involves a method including exposing a substrate to a metal oxy-halide precursor and a reducing agent to thereby deposit a film of the elemental metal on the substrate. The ratio of the reducing agent to the metal oxy-halide precursor is significantly greater than 1 and the deposited film contains no more than 1 atomic percentage oxygen. Molar ratios of at least 100:1 may be used.

In some embodiments, the deposited film has a halogen concentration of no more than 1E18 atoms/cm³. In some embodiments, the film is deposited by atomic layer deposition or pulsed nucleation layer deposition.

In some embodiments, the metal is molybdenum (Mo). In some such embodiments, the metal oxy-halide precursor is a molybdenum oxy-chloride. In some such embodiments, molybdenum tetrachloride oxide (MoOCl₄) or molybdenum dichloride dioxide (MoO₂Cl₂). In some such embodiments, the deposited film has a chlorine concentration of no more than 1E18 atoms/cm³. In some embodiments, the reducing agent is hydrogen (H₂). In some embodiments, the substrate temperature during deposition is between 350° C. and 800° C.

In some embodiments, the metal is tungsten (W). In some such embodiments, the metal oxy-halide precursor is of tungsten tetrafluoride oxide (WOF₄), tungsten tetrachloride oxide (WOCl₄), or tungsten dichloride dioxide (WO₂Cl₂).

In some embodiments, wherein exposing the substrate to an metal oxy-halide precursor and a reducing agent comprises charging a first set of charge vessels with a metal oxy-halide precursor and charging a second set of charge vessels with a reducing agent, wherein the total charge volume of the second set is greater than that of the first set. In some embodiments, the film of the elemental metal is at least 99 atomic percent metal.

Another aspect of the disclosure relates to a method including charging a first set of charge vessels with a molybdenum oxyhalide precursor and charging a second set of charge vessels with hydrogen, wherein the total charge volume of the second set is greater than that of the first set; and exposing a substrate to alternate pulses of the molybdenum oxyhalide precursor and hydrogen from the charge vessels to thereby deposit a film of elemental molybdenum on the substrate. The ratio of the reducing agent to the precursor is significantly greater than 1 and the deposited film contains no more than 1 atomic percentage oxygen. Molar ratios of at least 100:1 may be used.

In some embodiments, the deposited film has a halogen concentration of no more than 1E18 atoms/cm³.

In some embodiments, the substrate temperature during deposition is at least 500° C.

Another aspect of the disclosure relates to a method including charging a first set of charge vessels with a tungsten oxyhalide precursor and charging a second set of charge vessels with hydrogen, wherein the total charge volume of the second set is greater than that of the first set; and exposing a substrate to alternate pulses of the tungsten oxyhalide precursor and hydrogen from the charge vessels to thereby deposit a film of elemental tungsten on the substrate. The ratio of the reducing agent to the precursor is significantly greater than 1 and the deposited film contains no more than 1 atomic percentage oxygen. Molar ratios of at least 100:1 may be used.

In some embodiments, the deposited film has a halogen concentration of no more than 1E18 atoms/cm³. In some embodiments, the substrate temperature during deposition is at least 500° C.

Another aspect of the disclosure relates to a method including charging a first set of charge vessels with a molybdenum oxychloride precursor and charging a second set of charge vessels with hydrogen, wherein the total charge volume of the second set is greater than that of the first set; and exposing a substrate to alternate pulses of the molybdenum oxychloride precursor and hydrogen from the charge vessels to thereby deposit a film of elemental molybdenum on the substrate. The ratio of the reducing agent to the precursor is significantly greater than 1 and the deposited film contains no more than 1 atomic percentage oxygen. Molar ratios of at least 100:1 may be used. In some embodiments, the precursor is molybdenum tetrachloride oxide (MoOCl₄) or molybdenum dichloride dioxide (MoO₂Cl₂). In some embodiments, the deposited film has a chlorine concentration of no more than 1E18 atoms/cm³.

### BRIEF DESCRIPTION OF DRAWINGS

FIGS. 1A and 1B are schematic examples of material stacks that include a metal layer according to various embodiments.

FIGS. 2A, 2B, 3A, and 3B provide examples of structures in which the metal-containing stacks may be employed according to various embodiments.

FIG. 4 shows an example of apparatus that include a gas manifold system and that may be employed according to various embodiments.

FIG. 5 shows metal resistivity for various precursors and reducing agent:precursor molar ratios.

FIG. 6A is a block diagram of a processing system suitable for conducting deposition processes in accordance with embodiments described herein.

FIG. 6B provides one example of two deposition cycles of an ALD process according to various embodiments.

### DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Metal fill of features is used in semiconductor device fabrication to form electrical contacts. In some deposition processes, a metal nucleation layer is first deposited into the feature. In general, a nucleation layer is a thin conformal layer that serves to facilitate the subsequent formation of a bulk material thereon. The nucleation layer may be deposited to conformally coat the surfaces (sidewalls and, if present, bottom) of the feature. Conforming to these surfaces can be critical to support high quality deposition. Nucleation layers are often deposited using atomic layer deposition (ALD) or pulsed nucleation layer (PNL) methods.

In a PNL technique, pulses of reactant are sequentially injected and purged from the reaction chamber, typically by a pulse of a purge gas between reactants. A first reactant can be adsorbed onto the substrate, available to react with the next reactant. The process is repeated in a cyclical fashion until the desired thickness is achieved. PNL techniques are similar to ALD techniques. PNL is generally distinguished from ALD by its higher operating pressure range (greater than 1 Torr) and its higher growth rate per cycle (greater than 1 monolayer film growth per cycle). Chamber pressure during PNL deposition may range from about 1 Torr to about 400 Torr. In the context of the description provided herein, PNL broadly embodies any cyclical process of sequentially adding reactants for reaction on a semiconductor substrate. Thus, the concept embodies techniques conventionally referred to as ALD. In the context of the disclosed embodiments, chemical vapor deposition (CVD) embodies processes in which reactants are together introduced to a reactor for a vapor-phase or surface reaction. PNL and ALD processes are distinct from CVD processes and vice versa.

After the metal nucleation layer is deposited, bulk metal may be deposited by a CVD process. A bulk metal film is different from a metal nucleation layer. Bulk metal as used herein refers to metal used to fill most or all of a feature, such as at least about 50% of the feature. Unlike a nucleation layer, which is a thin conformal film that serves to facilitate the subsequent formation of a bulk material thereon, the bulk metal is used to carry current. It may be characterized by larger grain size and lower resistivity as compared to a nucleation film. In various embodiments, bulk material is deposited to a thickness of at least 50 Å.

There are various challenges in tungsten fill as devices scale to smaller technology nodes and more complex patterning structures are used. For example, conventional deposition of tungsten has involved the use of the fluorine-containing precursor tungsten hexafluoride (WF₆). However, the use of WF₆ results in some incorporation of fluorine into the deposited tungsten film. The presence of fluorine can cause electromigration and/or fluorine diffusion into adjacent components and damage contacts, thereby reducing the performance of the device. One challenge is reducing the fluorine content in a deposited tungsten film. The effect of a certain fluorine concentration increases as feature size decreases. This is because thinner films are deposited in smaller features with fluorine in the deposited tungsten film more likely to diffuse through thinner films.

Another challenge is achieving uniform step coverage, especially when depositing into high aspect ratio and complex structures such as 3D NAND structures. This is because it can be difficult to obtain uniform exposure to the deposition gases, particularly when some parts of the structure are more easily accessed by the deposition gases. In particular, lower vapor pressure metal precursors that are used to deposit low resistivity films tend to result in poor step coverage.

Provided herein are methods and apparatus for deposition of pure metal films. The methods involve the use of oxygen-containing precursors. Deposition of pure metal films from oxygen-containing precursors is challenging due to the ease of incorporation of oxygen into the films during the deposition process. If oxygen is incorporated, the resistivity increases. The methods and apparatus described herein may be implemented to deposition pure metal films that have less than 1 atomic percent oxygen in some embodiments.

The methods and apparatus may be implemented to form low resistance metallization stack structures for logic and memory applications. FIGS. 1A and 1B are schematic examples of material stacks that include a metal layer such as tungsten (W) or molybdenum (Mo) according to various embodiments. FIGS. 1A and 1B illustrate the order of materials in a particular stack and may be used with any appropriate architecture and application, as described further below with respect to FIGS. 2 and 3. In the example of FIG. 1A, a substrate 102 has a metal layer 108 is deposited thereon. The substrate 102 may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to form metallization stack structures on other substrates, such as glass, plastic, and the like.

In FIG. 1A, a dielectric layer 104 is on the substrate 102. The dielectric layer 104 may be deposited directly on a semiconductor (e.g., Si) surface of the substrate 102, or there may be any number of intervening layers. Examples of dielectric layers include doped and undoped silicon oxide, silicon nitride, and aluminum oxide layers, with specific examples including doped or undoped layers SiO₂ and Al₂O₃. Also, in FIG. 1A, a diffusion barrier layer 106 is disposed between the metal layer 108 and the dielectric layer 104. Examples of diffusion barrier layers including titanium nitride (TiN), titanium/titanium nitride (Ti/TiN), tungsten nitride (WN), tungsten carbon nitride (WCN), and molybdenum carbon nitride (MoCN). (It should be noted that any appropriate atomic ratios of the compound films may be used; that is, WCN refers to WCₓN_{y} compounds where x and y are greater than zero.) The metal layer 108 is the main conductor of the structure and may include a nucleation layer and a bulk layer.

FIG. 1B shows another example of a material stack. In this example, the stack includes the substrate 102, dielectric layer 104, with metal layer 108 deposited on the dielectric layer 104, without an intervening diffusion barrier layer. As in the example of FIG. 1A, the metal layer 108 may include a metal nucleation layer and a bulk metal layer. In some embodiments, the metal layer may be deposited on other metal layers, which may be for example, template or initiation layers. Still further, in some embodiments, a metal layer be deposited on a sacrificial layer that contains silicon and/or boron, such as described in U.S. Provisional Patent Application No. 62/588,869, filed Nov. 20, 2018.

While FIGS. 1A and 1B show examples of metallization stacks, the methods and resulting stacks are not so limited. For example, in some embodiments, a metal layer may be deposited directly on a Si or other semiconductor substrate.

The material stacks described above and further below may be employed in a variety of embodiments. FIGS. 2A, 2B, 3A, and 3B provide examples of structures in which the metal-containing stacks may be employed. FIG. 2A depicts a schematic example of a DRAM architecture including a metal buried wordline (bWL) 208 in a silicon substrate 202. The metal bWL is formed in a trench etched in the silicon substrate 202. Lining the trench is a conformal barrier layer 206 and an insulating layer 204 that is disposed between the conformal barrier layer 206 and the silicon substrate 202. In the example of FIG. 2A, the insulating layer 204 may be a gate oxide layer, formed from a high-k dielectric material such as a silicon oxide or silicon nitride material. FIG. 2B depicts an example of a via contact architecture including a metal via 209 providing connection to an underlying metal contact 210. The metal via 209 is surrounded by an insulating layer 204. A barrier layer may or may not be disposed between the metal via 209 and the insulating layer 204.

FIG. 3A depicts a schematic example of a metal wordline 308 in a 3D NAND structure 323. In FIG. 3B, a 2-D rendering of 3-D features of a partially-fabricated 3D NAND structure after metal fill, is shown including the metal wordline 308 and a conformal barrier layer 306. FIG. 3B is a cross-sectional depiction of a filled area with the pillar constrictions 324 shown in the figure representing constrictions that would be seen in a plan rather than cross-sectional view. The structures in FIGS. 2A, 2B, 3A, 3B are examples of applications for which the methods described herein may be implemented. Further examples include source/drain metallization.

The methods of metal layers include vapor deposition techniques such as PNL, ALD, and CVD. According to various implementations, a nucleation layer may be deposited prior to any fill of the feature and/or at subsequent points during fill of the feature.

PNL techniques for depositing tungsten nucleation layers are described in U.S. Pat. Nos. 6,635,965; 7,005,372; 7,141,494; 7,589,017, 7,772,114, 7,955,972 and 8,058,170. Nucleation layer thickness can depend on the nucleation layer deposition method as well as the desired quality of bulk deposition. In general, nucleation layer thickness is sufficient to support high quality, uniform bulk deposition. Examples may range from 10 Å-100 Å.

### Oxygen-Containing Metal Precursors

The oxygen-containing metal precursors used herein may be metal oxohalide precursors. Examples of metals that may be deposited include W, Mo, chromium (Cr), vanadium (V), and iridium (Ir). The metal oxohalide precursors include those of the form MₓO_{y}H_{z} where M is the metal of interest (e.g., W, Mo, Cr, V, or Jr) and H is a halide (e.g., fluorine (Fl), chlorine (Cl), bromine (Br), or iodine (I) and x, y, and z being any number greater than zero that can form a stable molecule. Specific examples of such precursors include: tungsten tetrafluoride oxide (WOF₄), tungsten tetrachloride oxide (WOCl₄), tungsten dichloride dioxide (WO₂Cl₂), molybdenum tetrafluoride oxide (MoOF₄), molybdenum tetrachloride oxide (MoOCl₄), molybdenum dichloride dioxide (MoO₂Cl₂), molybdenum dibromide dioxide (MoO₂Br₂), molybdenum oxoiodides MoO₂I and Mo₄O₁₁I, chromium dichloride dioxide (CrO₂Cl₂), iridium dichloride dioxide (IrO₂Cl₂), and vanadium oxytrichloride (VOCl₃). The metal oxohalide precursor may also be a mixed halide precursor that has two or more halogens.

Deposition of Pure Metal Films from the Oxygen-Containing Precursors

The deposition of pure metal films from metal oxohalide precursors can be performed using CVD (co-flow of precursor and reducing agent), pulsed CVD (pulsing of precursor or reducing agent or both with or without purges in between), or ALD (alternating pulsing of precursor and reducing agent with or without purges in between). Examples of reducing agents include hydrogen (H₂) silicon-containing reducing agents such as silane (SiH₄), boron-containing reducing agents such as diborane (B₂H₆), germanium-containing reducing agents such as germane (GeH₄), and ammonia (NH₃). In some embodiments, H₂ is used as there it is less susceptible to incorporation of its constituent atoms than other reducing agents and/or form less resistive films.

To deposit pure films with no more than one atomic percentage oxygen, the reducing agent to metal precursor ratio is significantly greater than 1, e.g., at least 20:1 or at least 50:1. Examples of temperatures may ranges from 350° C. to 800° C. for chlorine-containing precursors and 150° C. to 500° C. for fluorine-containing precursors. Examples of chamber pressures may range from 1 torr to 100 torr. The reducing agent:precursor ratio used to obtain pure films may be lower as temperature is increased. In some embodiments, the temperature for chlorine-containing precursors is at least 500° C. Higher pressures may also be used to reduce the reducing agent:precursor ratio as the partial pressure of the reducing agent is increased.

For processes such as ALD that employ pulses, the number of reducing agent pulses may be greater than the number of precursor pulses in some embodiments. The methods may be implemented using multiple charging vessels. An example apparatus is shown in FIG. 4, in which the 3 gas sources (precursor, H₂, and purge gases) are connected to charge vessels. The ratio of reducing agent to precursor may be characterized as the ratio of molecules that the substrate is exposed to and are available to react. It may be calculated from:

$$\frac{\begin{matrix}Reducing agent flow rate \times ( Reducing agent line charge time + \\ Reducing agent dose time )\end{matrix}}{\begin{matrix}Precursor flow rate \times \\ ( Precursor line charge time + Precursor dose time )\end{matrix}}$$

Line charges are pressurized distributions. Dose time refers to the amount of time the dose (also referred to a pulse) lasts. This may be simplified to the below where there is no line charge time:

$$\frac{Reducing agent flow rate \times Reducing agent dose time}{Precursor flow rate \times Precursor dose time}$$

The above expressions are molar ratios, with example molar ratios ranging from 50:1 to 10000:1, 50:1 to 2000:1, 100:1 to 10000:1, or 100:1 to 2000:1.

The ratio of reducing agent to precursor may be characterized as a volumetric ratio, which may be calculated as

$$\frac{Reducing flow rate at showerhead}{Precursor flow rate at showerhead}$$

The volumetric ratio may be 50:1 to 2000:1, for example.

The apparatus may include a gas manifold system, which provides line charges to the various gas distribution lines as shown schematically in FIG. 4. The manifolds provide the precursor gas, reducing gas and purge gas to the deposition chamber through valved charged vessels. The various valves are opened or closed to provide a line charge, i.e., to pressurize the distribution lines. In various embodiments, the number (an total charge volume) of reducing agent charge vessels may be greater than the number of precursor and/or purge gas charge vessels. Multiple pulses of reducing agent for every one pulse of precursor allows for fast reduction of the oxygen containing precursor to deposit the high purity, low resistivity metal film. In some embodiments, multiple charge vessels may be used for the precursor as well as the reducing agent. This allows multiple pulses to be introduced and enables complete reduction of the oxygen-containing precursors.

FIG. 5 shows the impact on metal resistivity using the methods described herein. Precursor 1 (MoCl₅) has no oxygen atoms, precursor 2 (MoOCl₄) has one oxygen atom, and precursor 3 (MoO₂Cl₂) has two oxygen atoms. Precursors 1 and 2 were deposited using conventional reducing agent:precursor ratios on a TiN film. As can be seen, the introduction of oxygen using a conventional ratio increases the resistivity (compare precursor 1 to precursor 2). Using the methods described herein, however, resistivity is decreased, even with two oxygen atoms.

Table 1 below provides characterizations of the resulting feature fill:

| | Precursor 1 | Precursor 2 | Precursor 3 |
|---|---|---|---|
| Cl atoms in precursor | 5 | 4 | 2 |
| O atoms in precursor | 0 | 1 | 2 |
| TiN attack | High | High | None |
| [Cl] in bulk film | 2E18 atoms/cm³ | 1E18 atoms/cm³ | 5E17 atoms/cm³ |
| [O] in bulk film | 1E20 atoms/cm³ | 2E20 atoms/cm³ | 1E20 atoms/cm³ |
| Resistivity at 20 nm | 17 | 23 | 14 |
| Feature Fill | Poor | Poor | Good |
| Temperature | 570° C. | 570° C. | 590° C. |
| Pressure | 25 T | 25 T | 40 T |
| Molar ratio of | 430:1 | 430:1 | 1000:1 |
| reducing agent (no. of | | | |
| (H₂) moles:no. of | | | |
| precursor moles) | | | |
| Volumetric ratio (H2 | 150:1 | 150:1 | 300:1 |
| flow:Precursor flow) | | | |

As can be seen from Table 1, the methods described herein (as exemplified by the Precursor 3 results) result in improved TiN attack, less Cl in the bulk film, and less 0 in the bulk film, with the amount of oxygen measured in the film below or near the detection limit of the measurement and comparable to the oxygen-free precursor.

The pure metal films are characterized as having at least 99 atomic % metal.

The methods described herein also may be used to eliminate or tune nucleation delay by modulating the reducing agent:precursor ratio. While conventional methods may have nucleation delay, the processes described herein can be run with no nucleation delay. Similarly, by modulating the reducing agent:precursor ratio, a desired nucleation delay may be introduced. This can have a significant impact on film morphology and electrical properties of the metal film.

The methods described herein enable the use of oxy-halide precursors that can lower the halide concentration in comparison to conventional metal halide MHₓ precursors. This feature minimizes etch and/or corrosion that occurs with halide species. Further, because the oxy-halide precursors have higher vapor pressure, step coverage may be improved but without sacrificing resistivity.

As indicated above, the methods may be implemented with vapor phase deposition techniques such as CVD as well as surface-mediated deposition techniques such as ALD. In CVD processes, the reducing agent and precursor may be introduced concurrently to the deposition chamber in a continuous flow process. In some embodiments, one or both of the reducing agent and precursor may be pulsed. FIG. 6B provides one example of two deposition cycles of an ALD process. In the example of FIG. 6B, both the reducing agent and the precursor are pulsed with purge operations between the pulses. In alternate embodiments, a purge may be omitted for one or both of the reactants.

### Apparatus

Any suitable chamber may be used to implement the disclosed embodiments. Example deposition apparatuses include various systems, e.g., ALTUS® and ALTUS® Max, available from Lam Research Corp., of Fremont, Calif., or any of a variety of other commercially available processing systems. The process can be performed on multiple deposition stations in parallel.

FIG. 6A is a block diagram of a processing system suitable for conducting deposition processes in accordance with embodiments described herein. The system 600 includes a transfer module 603. The transfer module 603 provides a clean, pressurized environment to minimize the risk of contamination of substrates being processed as they are moved between the various reactor modules. Mounted on the transfer module 603 is a multi-station reactor 609 capable of performing PNL, ALD, and CVD deposition according to embodiments described herein. Chamber 609 may include multiple stations 611, 613, 615, and 617 that may perform these operations sequentially or in parallel. For example, chamber 609 could be configured such that stations 611 and 613 perform PNL deposition, and stations 613 and 615 perform CVD. Each deposition station may include a heated wafer pedestal and a showerhead, dispersion plate or other gas inlet. Each station may also be connected to charge vessels and gas sources as described above with respect to FIG. 4.

Also mounted on the transfer module 603 may be one or more single or multi-station modules 607 capable of performing plasma or chemical (non-plasma) pre-cleans. The module may also be used for various other treatments, e.g., reducing agent soaking. The system 600 also includes one or more (in this case two) wafer source modules 601 where wafers are stored before and after processing. An atmospheric robot (not shown) in the atmospheric transfer chamber 619 first removes wafers from the source modules 601 to loadlocks 621. A wafer transfer device (generally a robot arm unit) in the transfer module 603 moves the wafers from loadlocks 621 to and among the modules mounted on the transfer module 603.

In certain embodiments, a system controller 629 is employed to control process conditions during deposition. The controller will typically include one or more memory devices and one or more processors. The processor may include a CPU or computer, analog and/or digital input/output connections, stepper motor controller boards, etc.

The controller may control all of the activities of the deposition apparatus. The system controller executes system control software including sets of instructions for controlling the timing, mixture of gases, chamber pressure, chamber temperature, wafer temperature, radio frequency (RF) power levels if used, wafer chuck or pedestal position, and other parameters of a particular process. Other computer programs stored on memory devices associated with the controller may be employed in some embodiments.

Typically there will be a user interface associated with the controller. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language. Alternatively, the control logic may be hard coded in the controller. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place.

The computer program code for controlling the deposition and other processes in a process sequence can be written in any conventional computer readable programming language: for example, assembly language, C, C++, Pascal, Fortran or others. Compiled object code or script is executed by the processor to perform the tasks identified in the program.

The controller parameters relate to process conditions such as, for example, process gas composition and flow rates, temperature, pressure, plasma conditions such as RF power levels and the low frequency RF frequency, cooling gas pressure, and chamber wall temperature. These parameters are provided to the user in the form of a recipe, and may be entered utilizing the user interface.

Signals for monitoring the process may be provided by analog and/or digital input connections of the system controller. The signals for controlling the process are output on the analog and digital output connections of the deposition apparatus.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

In some implementations, a controller 629 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 629, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 629, in some implementations, may be a part of or coupled to a computer that is integrated with, coupled to the system, otherwise networked to the system, or a combination thereof. For example, the controller 629 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 629 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in pedestal or chuck. Appropriately programmed feedback and control algorithms may be used with data from these sensors to maintain desired process conditions.

The foregoing describes implementation of embodiments of the disclosure in a single or multi-chamber semiconductor processing tool.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically comprises some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method, comprising:
exposing a substrate to a metal oxy-halide precursor and a reducing agent to thereby deposit a film of the elemental metal on the substrate, wherein the molar ratio of the reducing agent to the metal oxy-halide precursor is between 100:1 and 10000:1 and wherein the deposited film contains no more than 1 atomic percentage oxygen.

2. The method of claim 1, wherein the film is deposited by atomic layer deposition or pulsed nucleation layer deposition.

3. The method of claim 1, wherein the metal is molybdenum (Mo).

4. The method of claim 3, wherein the metal oxy-halide precursor is a molybdenum oxy-chloride.

5. The method of claim 4, molybdenum tetrachloride oxide (MoOCl₄) or molybdenum dichloride dioxide (MoO₂Cl₂).

6. The method of claim 4, wherein the deposited film has a chlorine concentration of no more than 1E18 atoms/cm³.

7. The method of claim 1, wherein the reducing agent is hydrogen (H₂).

8. The method of claim 1, wherein substrate temperature during deposition is between 350° C. and 800° C.

9. The method of claim 1, wherein the metal is tungsten (W).

10. The method of claim 9, wherein the metal oxy-halide precursor is tungsten tetrafluoride oxide (WOF₄), tungsten tetrachloride oxide (WOCl₄), or tungsten dichloride dioxide (WO₂Cl₂).

11. The method of claim 1, wherein exposing the substrate to an metal oxy-halide precursor and a reducing agent comprises charging a first set of charge vessels with a metal oxy-halide precursor and charging a second set of charge vessels with a reducing agent, wherein the total charge volume of the second set is greater than that of the first set.

12. The method of claim 1, wherein the film of the elemental metal is at least 99 atomic percent metal.

13. A method, comprising:
charging a first set of charge vessels with a molybdenum oxychloride precursor and charging a second set of charge vessels with hydrogen, wherein the total charge volume of the second set is greater than that of the first set; and
exposing a substrate to alternate pulses of the molybdenum oxychloride precursor and hydrogen from the charge vessels to thereby deposit a film of elemental molybdenum on the substrate, wherein the molar ratio of hydrogen to the molybdenum oxychloride precursor is between 100:1 and 10000:1 and wherein the deposited film contains no more than 1 atomic percentage oxygen.

14. The method of claim 13, molybdenum tetrachloride oxide (MoOCl₄) or molybdenum dichloride dioxide (MoO₂Cl₂).

15. The method of claim 13, wherein the deposited film has a chlorine concentration of no more than 1E18 atoms/cm³.

16. The method of claim 13, wherein the substrate temperature during deposition is at least 500° C.
